(19) United States
(12) Patent Application Publication
(10) Pub. No.: US 2008/0142068 A1
(43) Pub. Date: Jun. 19, 2008

(54) Direct Thermoelectric chiller assembly

(75) Inventors: John H. Bean, Wentzville, MO (US); Jonathan M. Lomas, Troy, MO (US)

Correspondence Address: LOWRIE, LANDO & ANASTASI, LLP, ONE MAIN STREET, SUITE 1100, CAMBRIDGE, MA, 02142, US

(73) Assignee: American Power Conversion Corporation, West Kingston, RI (US)

(21) Appl. No.: 11/640,652

(22) Filed: Dec. 18, 2006

(51) Int. Cl. H01L 37/00; H01L 35/28

(52) U.S. Cl. 136/201; 136/203

(57) ABSTRACT

A thermoelectric system comprising at least one thermoelectric module comprising a first side and a second side, and being configured to develop a temperate difference between the first side and the second side during operation, and comprising at least one first fluid manager configured to direct a first fluid along at least a first portion of the first side of the at least one thermoelectric module. Additional embodiments, cooling systems, and methods are further disclosed.

### BACKGROUND OF INVENTION

1. Field of Invention

Embodiments of the invention relate generally to a cooling unit. Specifically, aspects of the invention relate to a thermoelectric device in which fluid is directed along a side of a thermoelectric module.

2. Discussion of Related Art

Charge carriers traveling through an object, such as when an electric current travels through the object, may carry heat thereby heating one side of an object while cooling the other side of the object. This effect may be referred to as the “Peltier” effect, and objects designed to utilize this effect in cooling and heating devices may be referred to as thermoelectric modules.

Some thermoelectric modules may carry heat using current from one end of a metal or semiconductor to the other end of the metal or semiconductor. The current may induce a temperature difference such that one side of the single metal or single semiconductor becomes warmer while the other side of the single metal or single semiconductor becomes cooler.

To increase the heating and cooling effects, other thermoelectric modules may carry heat using a current through an alternating array of two different materials, for example, p-type and n-type semiconductors. The array may be arranged such that each element of the array is electrically coupled to a neighbor of a different material type and through a different side of the thermoelectric module. When a potential is applied across the array, current through exists through the array moving to one side of the thermoelectric module through an element of the array made from a first material and then back to the other side of the thermoelectric module through an element of the array made from the second material. In such an arrangement, current exists in a back and forth pattern from one side of the thermoelectric module to the other side of the thermoelectric module along all of the elements of the array.

Heat, in either type of thermoelectric module, is carried from one side of the thermoelectric module to the other side by charge carriers (i.e., electrons or holes). In the later type of thermoelectric module, materials are chosen so that the charge carriers of one material are electrons and the charge carriers of the other material are holes. With such a set of materials, the charge carriers in elements made from both materials may flow towards the same side of the thermoelectric module when a current exists through the array of elements arranged as described above. Therefore, heat will move towards the same side of the thermoelectric module despite current in opposite directions through elements made from different materials.

A device designed to use one or more thermoelectric modules to provide heating and/or cooling may be referred to as a thermoelectric device. To take advantage of the heat movement in a thermoelectric module, prior art thermoelectric devices 100, as illustrated in FIG. 1, may include cold plates 101, 103 that transfers heat between each side 105, 107 of the thermoelectric module 109 and two working fluids being carried by pipes 111, 113 near the thermoelectric module 109. The working fluid in the pipe 111 connected to the hot side 105 of the thermoelectric module 109 will heat up while the working fluid in the pipe 113 connected to the cold side 107 of the thermoelectric module 109 will cool down. The heated fluid may be used to heat an object or space, and the cooled fluid may be used to cool an object or space.

To facilitate heat transfer between the cold plates 101, 103 and the thermoelectric module 109, a pressure may be applied to press the cold plates 101, 103 and the sides 105, 107 of the thermoelectric module 109 together and eliminate large gaps. This pressure is typically limited so that the thermoelectric module 109 may shrink and expand as its temperature changes. To further facilitate heat transfer between the sides 105, 107 of the thermoelectric module 109 and the cold plates 101, 103, micro-scale voids caused by surface imperfections of the cold plates 101, 103 and the sides 105, 107 of the thermoelectric module 109 may be filled by applying a layer of a thermal interface material 115 between the cold plates 101, 103 and the sides 105, 107 of the thermoelectric module 109.

### SUMMARY OF INVENTION

One aspect of the invention includes a thermoelectric system. Some embodiments include at least one thermoelectric module comprising a first side and a second side. In some embodiments, the at least one thermoelectric module is configured to develop a temperate difference between the first side and the second side during operation. Some embodiments include at least one first fluid manager configured to direct a first fluid along at least a first portion of the first side of the at least one thermoelectric module.

In some embodiments, the first fluid includes at least one of water and a composition including glycol. In some embodiments, the at least one thermoelectric module comprises at least one p-type semiconductor and at least one n-type semiconductor. In some embodiments, the at least one thermoelectric module comprises at least one first fluid resistant layer configured to electrically insulate the first fluid from the first side. In some embodiments, the at least one first fluid manager comprises at least one first fluid supply and at least one first fluid return. Some embodiments further includes a first fluid supply manager connection configured to direct the first fluid to the at least one first fluid supply and a first fluid return connection configured to direct the first fluid from the at least one first fluid return. In some embodiments, the at least one first fluid supply comprises a plurality of first fluid supplies. In some embodiments, the at least one first fluid manager further comprises at least one first fluid director forming at least one channel configured to direct at least a portion of the first fluid from the at least one first fluid supply to the at least one first fluid return.

In some embodiments, the at least one first fluid manager comprises at least one first turbulence element configured to generate turbulence in the first fluid along the at least first portion of the first side of the at least one thermoelectric module. In some embodiments, the at least one first turbulence element comprises at least one first protrusion in a channel of the first fluid manager. Some embodiments further includes at least one second fluid manager configured to direct a second fluid along at least a second portion of the second side of the at least one thermoelectric module.

In some embodiments, the at least one thermoelectric module includes a plurality of thermoelectric modules, each having a respective first side and second side. In some embodiments, the at least one first fluid manager includes a plurality of first fluid managers each configured to direct at least a first portion of the first fluid proximally along at least a first portion of the respective first side of each thermoelectric module of the plurality of thermoelectric modules. In some embodiments, the at least one second fluid manager includes a plurality of second fluid managers each configured to direct at least a second portion of the second fluid proximally along at least a second portion of the respective second side of each thermoelectric module of the plurality of thermoelectric modules. In some embodiments, the at least one thermoelectric module is configured such that the first side and the second side experience a temperature difference of about twenty degrees Celsius when the at least one thermoelectric module is in operation.

In some embodiments, the first side comprises a hot side of the at least one thermoelectric module and the second side comprises a cold side of the at least one thermoelectric module. In some embodiments, the at least one thermoelectric module is configured such that the hot side and first fluid experience a first temperature difference of about four degrees Celsius during operation of the at least one thermoelectric module and the cold side and second fluid experience a second temperature difference of about nine degrees Celsius during operation of the at least one thermoelectric module.

In some embodiments, the at least one thermoelectric module includes a plurality of thermoelectric modules, each having a respective first and second side. In some embodiments, the at least one first fluid manager includes a plurality of first fluid managers each configured to direct at least a first portion of the first fluid proximally along a respective first portion of a respective first side of each thermoelectric module of the plurality of thermoelectric modules. Some embodiments further includes at least one power source electrically coupled to the plurality of thermoelectric modules. In some embodiments, the plurality of thermoelectric modules are electrically coupled to one another.

In some embodiments, each thermoelectric module of a first subset of the plurality of thermoelectric modules is electrically coupled in series to other thermoelectric modules of the first subset. In some embodiments, the first subset is electrically coupled in parallel to a plurality of second subsets of the plurality of thermoelectric modules. In some embodiments, the first subset includes a number of thermoelectric modules corresponding to a voltage output of the power supply. In some embodiments, the plurality of second subsets includes a number of subsets corresponding to a power output of the power supply.

One aspect of the invention includes a method of cooling. In some embodiments, the method includes generating a potential difference across at least one thermoelectric module to cool a first side of the at least one thermoelectric module and warm a second side of the at least one thermoelectric module, and directing a first fluid along at least a first portion of at least one of the first side and the second side.

In some embodiments, the first fluid includes at least one of water and a composition including glycol. In some embodiments, directing the first fluid includes directing the first fluid into at least one first fluid supply of at least one fluid manager and directing the first fluid out of at least one first fluid return of the at least one fluid manager. In some embodiments, directing the first fluid includes directing the first fluid through at least one fluid directing channel disposed in at least one fluid manager between the at least one fluid supply and the at least one fluid return. In some embodiments, directing the first fluid includes generating turbulence in the first fluid as the first fluid is directed through the at least one fluid directing channel.

In some embodiments, directing the first fluid includes directing the first fluid along at least the first portion of the first side and directing a second fluid along at least a second portion of the second side. In some embodiments, generating the potential difference includes generating a temperature difference between the first side and second side of about twenty degrees Celsius. In some embodiments, generating the potential difference includes generating a first temperature difference between the first side and first fluid experience of about nine degrees Celsius and generating a second temperature difference between the second side and second fluid of about four degrees Celsius. In some embodiments, the at least one thermoelectric module includes a plurality of thermoelectric modules.

Some embodiments further comprise electrically coupling the plurality of thermoelectric modules to one another. In some embodiments, electrically coupling comprises electrically coupling each thermoelectric module of a first subset of the plurality of thermoelectric modules in series to other thermoelectric modules of the first subset. In some embodiments, electrically coupling comprises electrically coupling the first in parallel to a plurality of second subsets of the plurality of thermoelectric modules. In some embodiments, the first subset includes a number of thermoelectric modules corresponding to a voltage output of a power supply coupled to the plurality of thermoelectric modules. In some embodiments, the plurality of second subsets includes a number of subsets corresponding to a power output of the power supply.

One aspect of the present invention includes a cooling system. In some embodiments, the cooling system includes at least one first fluid inlet, at least one first fluid outlet, and at least one direct thermoelectric device disposed between the at least one first fluid inlet and the at least one first fluid outlet, the at least one direct thermoelectric device being configured to cool at least one first fluid supplied from the at least one first fluid inlet and supply the at least one cooled first fluid to the at least one first fluid outlet.

In some embodiments, the at least one first fluid includes at least one of water and a composition including glycol. In some embodiments, the at least one direct thermoelectric device comprises at least one thermoelectric module comprising a first side, and at least one first fluid manager configured to accept the at least one first fluid from the at least one first fluid inlet, direct the at least one first fluid along at least a first portion of the first side of the at least one thermoelectric module, and exhaust the at least one cooled first fluid to the at least one first fluid outlet.

In some embodiments, the at least one thermoelectric module comprises at least one first fluid resistant layer configured to electrically separate the first fluid from the first side. In some embodiments, the at least one first fluid manager comprises at least one first turbulence element configured to generate turbulence proximally along the at least first portion of the first side of the at least one thermoelectric module.

In some embodiments, the cooling system includes at least one second fluid inlet, and at least one second fluid outlet. In some embodiments, the at least one direct thermoelectric device is disposed between the at least one second fluid inlet and the at least one second fluid outlet, the at least one direct thermoelectric device being further configured to warm at least one second fluid supplied from the at least one second fluid inlet and supply the at least one warmed second fluid to the at least one second fluid outlet. In some embodiments, the at least one direct thermoelectric device comprises at least one thermoelectric module comprising a first side and a second side, at least one first fluid manager configured to accept the at least one first fluid from the at least one first fluid inlet, direct the at least one first fluid along at least a first portion of the first side of the at least one thermoelectric module, and exhaust the at least one cooled first fluid to the at least one first fluid outlet, and at least one second fluid manager configured to accept the at least one second fluid from the at least one second fluid inlet, direct the at least one second fluid along at least a second portion of the second side of the at least one thermoelectric module, and exhaust the at least one warmed second fluid to the at least one second fluid outlet.

In some embodiments, the at least one thermoelectric module is configured such that the first side and second side experience a temperature difference of about twenty degrees Celsius when the at least one thermoelectric module is in operation. In some embodiments, the at least one thermoelectric module is configured such that the first side and the cooled first fluid experience a first temperature difference of about nine degrees Celsius during operation of the at least one thermoelectric module and the second side and warmed second fluid experience a second temperature difference of about four degrees Celsius during operation of the at least one thermoelectric module.

### BRIEF DESCRIPTION OF DRAWINGS

The accompanying drawings are not intended to be drawn to scale. In the drawings, each identical or nearly identical component that is illustrated in various figures is represented by a like numeral. For purposes of clarity, not every component may be labeled in every drawing. In the drawings:

FIG. 1 is a cross-sectional view of a thermoelectric device known in the prior art;

FIG. 2 is a cross-sectional view of a thermoelectric module in accordance with an embodiment of the invention;

FIG. 3 is a plan view of multiple fluid flow managers in accordance with an embodiment of the invention;

FIG. 4 is an enlarged view of a single fluid flow manager shown in FIG. 3;

FIG. 5 is a view of a fluid supply manager in accordance with an embodiment of the invention;

FIG. 6 is a second view of the fluid supply manager of FIG. 5;

FIG. 7 is an exploded view of a direct thermoelectric device in accordance with an embodiment of the invention; and

FIG. 8 is a perspective view of the direct thermoelectric device shown in FIG. 7 in an assembled condition.

### DETAILED DESCRIPTION

This invention is not limited in its application to the details of construction and the arrangement of components set forth in the following description or illustrated in the drawings. The invention is capable of other embodiments and of being practiced or of being carried out in various ways. Also, the phraseology and terminology used herein is for the purpose of description and should not be regarded as limiting. The use of “including,” “comprising,” “having,” “containing,” “involving,” and variations thereof herein, is meant to encompass the items listed thereafter and equivalents thereof as well as additional items.

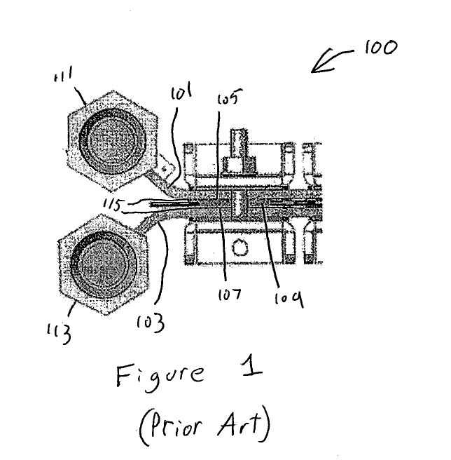

In accordance with one aspect of the invention, it is recognized that traditional thermoelectric devices may inefficiently transfer heat between the sides of thermoelectric modules and working fluids. As described above, in traditional thermoelectric devices, such as the one sown in FIG. 1, heat is transferred between sides 105, 107 of the thermoelectric module 109 and working fluids through intermediate heat transferring elements, such as cold plates 101, 103 and layers of thermal interface materials 115. Inefficiency in heat transfer in such a traditional thermoelectric device 100 is introduced because of these intermediate heat transferring elements. Each intermediate heat transferring element dissipates heat and decreases the thermal conductivity from the thermoelectric module 100 to the working fluids. Specifically, the layers of thermal interface materials 115 used to fill micro-scale void between cold plates 101, 103 and sides 105, 107 of the thermoelectric module 109 generally have relatively low thermal conductivities compared to the cold plates 101, 103. Cold plates 101, 103 and a thermoelectric module 109 without surface imperfections, which would not require layers of thermal interface material 115 to fill micro-scale voids, such as machined and vacuum brazen cold plates and thin wall micro channel cold plates, are prohibitively expensive to manufacture. Similarly, layers of thermal interface materials 115 that have thermal conductivities near a thermal conductivity of the cold plates 101, 103 are also prohibitively expensive. As a result, affordable traditional thermoelectric devices 100 remain inefficient.

For example, typical traditional thermoelectric devices typically generate about 1200 Watts of cooling using about 1600 Watts to about 1700 Watts of power. In operation, the temperature between hot sides and the cold sides of thermoelectric modules in such chillers may be about thirty-three degrees Celsius. A temperature difference between the surface of the hot side and the hot working fluid may be about seven degrees Celsius. A temperature difference between the surface of the cold side and the cold working fluid may be about fifteen degrees Celsius. Ideally, these temperature differences would be reduced towards zero degrees Celsius.

In general, at least one embodiment of the invention is directed at economically improving the efficiency of a thermoelectric device. Specifically, at least one embodiment of the invention is directed to a thermoelectric device in which heat is transferred between sides of a thermoelectric module and the working fluids without the use of cold plates or thermal interface materials. Instead, in at least one embodiment of the invention, the working fluids travel proximally along the sides of the thermoelectric modules.

The term “thermoelectric device” should be understood to refer to any device in which a thermoelectric module is used, including devices in which the thermoelectric module is used to chill or cool an object and/or space and devices in which the thermoelectric modules is used to heat or warm an object and/or space. The term “working fluid” should be understood to include any fluid which transfers heat to and/or from a thermoelectric module, including one or more liquids (e.g., water, a composition comprising glycol, a refrigerant not containing water) and/or one or more gases (e.g., air).

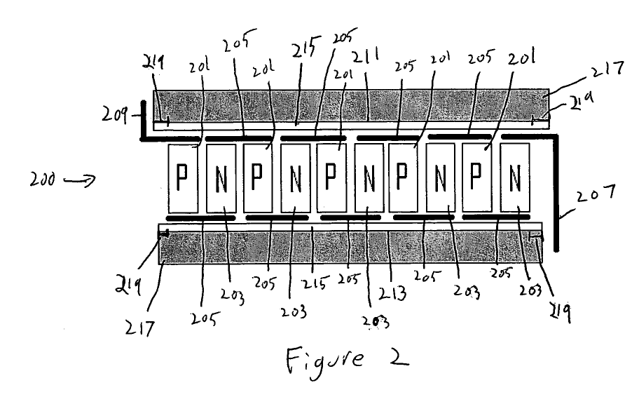

FIG. 2 illustrates a cross-sectional view of a thermoelectric module 200 in accordance with at least one embodiment of the invention. The thermoelectric module 200 may include a plurality of conductive elements 201, 203. A first portion of the plurality of conductive elements may include p-type semiconductor elements, each indicated at 201. A second portion of the plurality of conductive elements may include n-type semiconductor elements, each indicated at 203. As illustrated in FIG. 2, the n-type semiconductor elements 203 may alternate with the p-type semiconductor elements 201. It should be understood that embodiments of the invention are not limited to any particular material type or arrangement of conductive elements.

In at least one embodiment, the n-type semiconductor elements 203 may be electrically coupled to neighboring p-type semiconductor elements 201 through alternative sides of the thermoelectric module 200. As illustrated in FIG. 2, a plurality of conductors, each indicated at 205, may be disposed on alternative sides of the thermoelectric module 200 to electrically couple neighboring p-type semiconductor elements 201 and n-type semiconductor elements 203.

In at least one embodiment, the thermoelectric module may 200 include conductive leads 207, 209 through which a potential may be applied across the plurality of semiconductor elements 201, 203. The conductive leads 207, 209 may be electrically coupled to a power source (not shown) through a fluid flow manager as described below.

In operation, a high potential may be applied to conductive lead 207 while a low potential may be applied to conductive lead 209. The potential difference may cause a current from the high potential lead to the low potential lead through the plurality of conductive elements 201, 203. In the illustrated example, when such a potential difference exists, the current passes from the top side 211 of the thermoelectric module 200 passing through the p-type semiconductor elements 201 to the bottom side 213 of the thermoelectric module 200 and then passing through the n-type semiconductor elements 203 back to the top side 211. This pattern of current continues from the high potential source to the low potential source.

Charge carriers traveling through the conductive elements 201, 203 carry heat from one side of the thermoelectric module 200 to the other. In p-type semiconductor elements 201, charge carriers (i.e. holes (positive charge carriers)) travel from high potentials to low potentials. In n-type semiconductor elements 203, charge carriers (i.e., electronic (negative charge carriers)) travel from low potentials to high potentials. When a high potential is applied to conductive lead 207 and a low potential is applied to conductive lead 209, the holes flow from the bottom of the p-type semiconductor elements 201 to the top and electrons flow from the bottom of the n-type semiconductor elements 203 to the top. This flow of charge carrier from the bottom side 213 of the thermoelectric module 200 to the top side 211 of the thermoelectric module 200 causes the top side 211 to warm and the bottom side 213 to cool. Reversing the potentials may allow the charge carrier to flow in opposite directions and the bottom side 213 to heat while the top side 211 cools.

The amount of heat moved from the cooled side of the thermoelectric module 200 to the warmed side of the thermoelectric module 200 may vary based on the number, resistivity, height, area, and thermal conductivity of the conductive elements 201, 203, the voltage applied, the current applied, the Seebeck coefficient, and/or the temperature of the sides. In some embodiments, the amount of heat may be approximated by:

$$H = 2 N [ {SIT}_{c} - \frac{{I}^{2} RL}{2 A} - \frac{KA ( {T}_{h} - {T}_{c} )}{L} ] , \qquad ( 1 )$$

where H is the heat transferred, N is the number of p-type and n-type semiconductor element pairs 201, 203, S is the Seebeck coefficient which may vary based on temperature of the thermoelectric module 200, I is the current through the thermoelectric module 200, T_{c} is the temperature of the cold side (e.g., 213) of the thermoelectric module 200, Tₕ is the temperature of the hot side (e.g., 211) of the thermoelectric module 200, R is the electrical resistivity of the semiconductor elements 201, 203, L is the height of the semiconductor elements 201, 203, A is the cross sectional area of the semiconductor elements 201, 203, and K is the thermal conductivity of the semiconductor elements 201, 203. In one implementation, the thermoelectric module 200 may include a High Performance Module available commercially from TE Technology, Inc., Traverse City, Mich., such as the HP-199-1.4-0.8 thermoelectric module.

In some embodiments, a protective layer 215 may be disposed on one or both of the top and bottom sides 211, 213 of the thermoelectric module 200. The protective layer 215 may isolate the electrically active elements (e.g., conductive elements 201, 203, conductors 205, conductive leads 207, 209) from the surrounding environment. The protective layer 215 may comprise a fluid resistant layer or coating configured to isolate the electrically active elements from water flowing proximally along the top and/or bottom sides 211, 213 of the thermoelectric module 200 through at least one fluid flow manager 217, as described below. In one implementation, the protective layer 215 may include a metal flashing and/or a ceramic flashing.

In some implementations, the thermoelectric module 200 may include one or more thermally inactive or less active portions 219. As illustrated in FIG. 2, in some implementations, the thermally inactive portions 219 may include a portion of the protective layer 215 proximate to the edges of the thermoelectric module 200 near which no thermoelectric elements 201, 203 are disposed. The thermally inactive portions 219 may be used for creating a fluid seal with the fluid flow manager 217 by positioning an O-ring or other sealant proximate to the thermally inactive portions 219.

In some implementations, the surface area of the thermoelectric module 200 may be increased by adding one or more pens (not shown), indentations (not shown), and/or protrusions (not shown) to the protective layers 215 of the thermoelectric module 200. Such pens or indentations may also increase turbulence of a working fluids traveling proximally along the sides, as discussed in more detail below.

As illustrated in FIG. 2, in some embodiments of the invention, the thermoelectric module 200 may be disposed between two fluid flow managers, each indicated at 217. The fluid flow managers 217 may be configured to direct a working fluid over the respective protective layers 215, as described in more detail below.

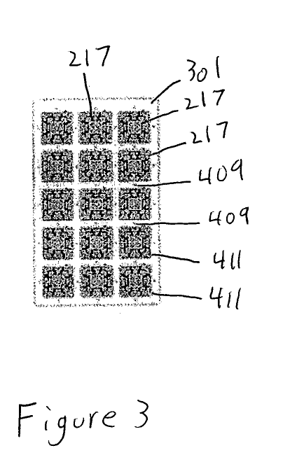

FIG. 3 illustrates a plurality of fluid flow managers 217 arranged on a surface 301 to accommodate a plurality of thermoelectric modules 200. Each fluid flow manager 217 may be configured to couple to a side of a respective thermoelectric module (e.g., 200) and direct a working fluid along the side of the respective thermoelectric module, as illustrated in FIG. 2. In various embodiments of the invention, the fluid flow managers 217 may be made from any material. In one implementation, the fluid flow managers 217 may be made from plastic.

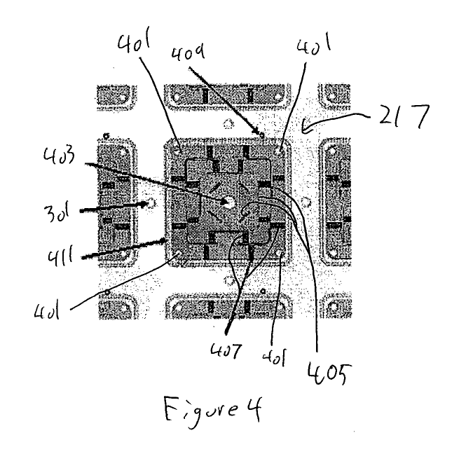

FIG. 4 illustrates an enlarged view of one of the fluid flow managers 217 of FIG. 3 in accordance with at least one embodiment of the invention. As discussed above, the fluid flow manager 217 may be configured to direct a working fluid proximally along at least a portion of one side of the thermoelectric module 200. In one embodiment, the fluid flow manager 217 may be placed adjacent to the thermoelectric module 200 so that working fluid traveling through the fluid flow manager 217 travels proximately along at least a portion of the outer surface of a protective layer 215 of the thermoelectric module 200. The fluid flow manager 217 of FIG. 4 is illustrated and described as an example only. It should be understood that embodiments of the invention may include any type of fluid flow manager in any configuration.

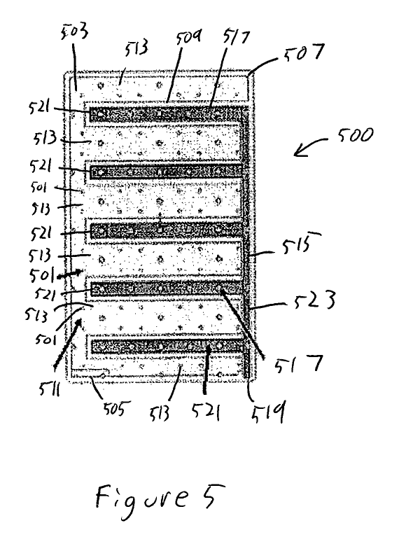

As illustrated in FIG. 4, the fluid flow manager 217 may include one or more fluid supplies, each indicated at 401. The fluid supplies 401 in the illustrated example include holes in the fluid flow manager 217 that connect to a fluid supply manager (not shown in FIG. 4), as described below with respect to FIG. 5, through a surface of the fluid supply manager (not shown in FIG. 4) to which the fluid flow manager 217 is coupled, as discussed below. The working fluid may enter the fluid flow manager 217 through the one or more fluid supplies 401 from the fluid supply manager (not shown in FIG. 4), as described below with respect to FIG. 5.

Embodiments of the fluid flow manager 217 may also include one or more fluid returns 403. The fluid return 403 illustrated in FIG. 4 includes a hole through surface 301 connected to the fluid supply manager (not shown in FIG. 4) through a hole in a surface of the fluid supply manager (not shown in FIG. 4), as discussed below with respect to FIG. 5. The working fluid may exit the fluid flow manager 217 through the one or more fluid returns 403 into the fluid supply manager (not shown in FIG. 4), as discussed below with respect to FIG. 5.

Embodiments of the fluid flow manager 217 may also include one or more fluid directors 405 that form one or more fluid channels through which the working fluid may flow from the one or more fluid supplies 401 to the one or more fluid returns 403. The fluid directors 405 may include a wall or other blocking surface through which the working fluid may not pass. The fluid directors 405 may be configured to direct the working fluid by forming a fluid seal with the protective layer 215 of the thermoelectric module 200 and blocking the flow of the working fluid in particular directions. Gaps in/between the fluid directors 405 may allow the working fluid to flow in desired directions only. In some embodiments, the combination of fluid directors 405, fluid supplies 401, and fluid returns 403 may be arranged to produce a low pressure of the fluid passing through the channels and to keep the working fluid traveling near the thermoelectric module for a longer time than a direct path from the one or more fluid supplies 401 to the one or more fluid returns 403.

In operation, the fluid channels of the illustrated embodiment may direct the working fluid proximally along the thermoelectric module 200 from each of the one or more fluid supplies 401 to the fluid return 403. The working fluid travels through each channel such that the working fluid that enters the fluid flow manager 217 from each of the fluid supplies 401 travels along about a quarter of the surface of the fluid flow manager 217 and about a quarter of the surface of the thermoelectric module 200 before exiting the fluid flow manager 217 through the fluid return 403. The combined flows of the working fluid through all of the channels of the fluid flow manager 217 from all of the fluid supplies 401 to the fluid return 403 results in the working fluid traveling along about the entire surface of the fluid flow manager 217 and about the entire surface of the thermoelectric module 200.

In some embodiments, the fluid flow manager 217 may include one or more turbulence elements 407 configured to introduce and/or increase turbulence in the working fluid as the working fluid travels from the fluid supply 401 to the fluid return 403 (e.g., through the channels). Molecules of the working fluid traveling nearest to the thermoelectric module 200 may transfer heat most efficiently with the thermoelectric module 200. Ideally, each molecule of the working fluid would spend about the same amount of time being nearest to the thermoelectric module 200. A non-turbulent or laminar flow of the working fluid, however, generally results in molecules of the working fluid remaining at a substantially constant distance from the thermoelectric module 200 throughout the flow from the fluid supply 401 to the fluid return 403, so relatively few molecules of the working fluid spend much time near the thermoelectric module 200 in such non-turbulent or laminar flows of the working fluid.

The turbulence elements 407 may cause the movement of molecules within the working fluid flow so that more molecules of the working fluid move near the thermoelectric module 200 than in a non-turbulent or laminar flow of the working fluid. The turbulence elements 407 may include bumps, protrusions, or any other elements that may disrupt a laminar or non-turbulent flow of the working fluid.

As illustrated in FIG. 4, the fluid flow manager 217 may be disposed on the surface 301. In some embodiments, the surface 301 may include an opposite surface of the fluid supply manager (not shown in FIG. 4), as discussed below. In some embodiments, the surface 301 may include one or more electrical contacts 409 configured to connect a particular thermoelectric module 200 disposed proximate to the fluid flow manager 217 to a power source. In some embodiments, the one or more electrical contacts 409 may include high and low potential sources configured to connect to the conductive leads 207, 209 of the thermoelectric module 200 and generate a current. In other embodiments, the electrical contacts 409 may include only one of the high and low potential sources. The other of the high and low potential sources may be arranged as an electrical contact on a surface of another fluid supply manager proximate to the other side of the thermoelectric module 200, as described below.

The fluid flow manager 217 may be surrounded by an O-ring 411 or other fluid proof design element that forms a fluid seal when the thermoelectric module 200 is placed proximate to the fluid flow manager 217. The O-ring 411 may form a fluid seal between the surface 301 and the thermally inactive portion 219 of the thermoelectric module 200, for example.

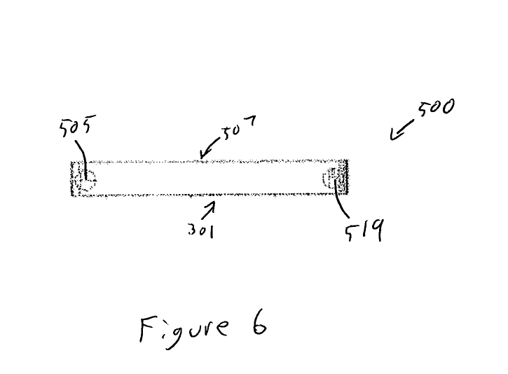

FIGS. 5 and 6 illustrate two views of a fluid supply manager 500. In some embodiments, the fluid supply manager 500 may be configured to supply the working fluid to the fluid supplies 401 of one or more fluid flow managers 217 and to accept an exhaust of the working fluid from the fluid returns 403 of the one or more fluid flow managers 217. In various embodiments of the invention, the fluid supply manager 500 may be made from any material. In one implementation, the fluid supply manager 500 may be made from plastic.

As illustrated in FIG. 5, a perspective view of a fluid supply manager 500, in some embodiments, the fluid supply manager 500 may include a fluid supply path 503 arranged to direct the working fluid from a working fluid source 505 to one or more fluid outlets 501 of the fluid supply manager 500 through which fluid is supplied to the fluid supplies 401 of the one or more fluid flow managers 217. In the illustrated embodiment, the fluid outlets 501 of the fluid supply manager 500 include holes in a surface 507 through which the working fluid may flow to the opposite surface 301 on which the one or more fluid flow managers 217 may be mounted. The fluid supply manager 500 may be configured to supply each fluid flow manager 217 with a substantially constant and/or similar volume of the working fluid.

In one implementation, the fluid supply path 503 may include walls or other fluid blocking elements 509 arranged on the surface 507 and configured so that the working fluid flows from the fluid source 505 to each of the fluid outlets 501. As illustrated in the embodiment of FIG. 5, a main fluid supply channel 511 may supply portions of the working fluid from the working fluid source 505 to tributary fluid supply channels 513. Each tributary fluid supply channel 513 may then direct fluid to the fluid outlets 501 arranged along the tributary fluid supply channel.

The fluid supply manager 500 may include a fluid return path 515 configured to accept working fluid through one or more fluid inlets 517. The fluid inlets 517 may accept exhausted working fluid from the one or more fluid returns 403 of the fluid flow manager 217. The fluid return path 515 may be configured to direct working fluid from the one or more fluid inlets 517 to a fluid exhaust 519. The fluid return path 515, similar to the fluid supply path 503, may include one or more tributary fluid return channels 521 connected to a main fluid return channel 523. Each tributary fluid return channel 515 may be configured to direct the working fluid from fluid inlets 517 arranged along the tributary fluid return channels 515 to the main fluid return channel 523. The main fluid return channel 523 may be configured to direct the working fluid from the tributary fluid return channels 517 to the fluid exhaust 519. The fluid return path 515 may be arranged on the same surface of the fluid supply manager 500 as the fluid return path 503 and separated by the walls 509.

FIG. 6 illustrates a view of the fluid supply manager 500 from the bottom of the fluid supply manager 500. Although the fluid source 505 and fluid exhaust 519 are arranged on the same side of the fluid supply manager 500, it should be recognized that any arrangement of elements of the fluid supply manager 500 may be used in various embodiments of the invention.

In some embodiments, the fluid supply manager 500 may include electrical connections (not shown) to the electric contacts 409 of the fluid flow managers 217 to supply power to the thermoelectric modules 200 as described above. The electrical connections may be arranged to connect the thermoelectric modules in parallel, series, or a combination or parallel and series, as discussed in more detail below. In one implementation, the electrical connections may be insulated from the working fluid flowing through the fluid supply manager 500. In one implementation, the electrical connections may be disposed within the walls 509.

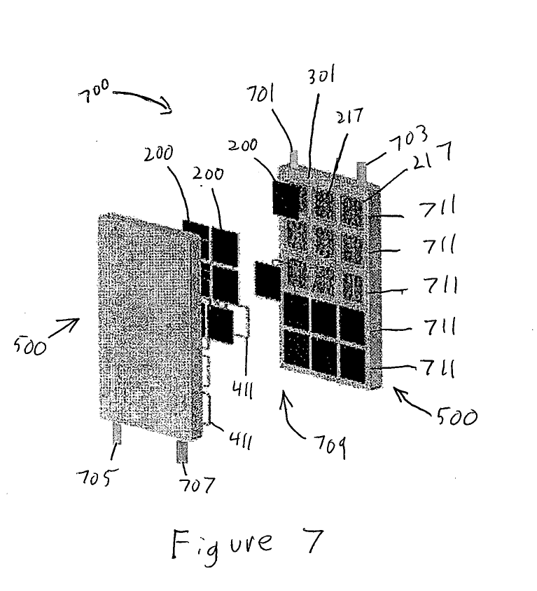

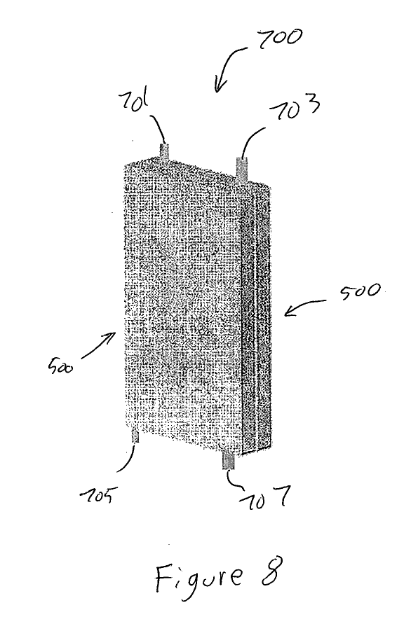

FIGS. 7 and 8 illustrate two views of a thermoelectric device 700 in accordance with at least one embodiment of the invention that includes thermoelectric modules 200, fluid flow managers 217 and fluid supply managers 500 (each having a backing which blocks the view of some components described above). FIG. 7 illustrates an exploded view of the direct thermoelectric device 700. FIG. 8 illustrates an assembled view of the direct thermoelectric device 700. Although the thermoelectric device 700 illustrated in FIGS. 7 and 8 includes a plurality of thermoelectric modules 200, a plurality of fluid flow managers 217, and a pair of fluid supply managers, each indicated at 500, it should be understood that embodiments of the invention may include more or fewer thermoelectric modules 200, fluid flow managers 217 and fluid supply managers 500, including a single thermoelectric module 200 and a single pair of fluid flow managers 217 connected directly to supplies of working fluid. It should also be understood that embodiments of the present invention may include fluid flow managers 217 on only a single side of the thermoelectric modules 200 rather than both sides as illustrated in FIGS. 7 and 8. In such embodiments, traditional cold plates or other methods may be used to transfer heat to and/or from the other side of the thermoelectric modules 200.

As illustrated in FIG. 7, the thermoelectric device 700 may include or connect to one or more pipes 701, 703, 705, 707. The pipes may include a hot side supply pipe 701 configured to supply a first working fluid to a first fluid supply manager (e.g., to a fluid source 505 from a fluid inlet of a cooling system (not shown)), a hot side return pipe 703 configured to accept an exhaust of the first working fluid from the first fluid supply manager (e.g., from a fluid exhaust 519 to a fluid outlet of a cooling system (not shown)), a cold side supply pipe 705 configured to supply a second working fluid to a second fluid supply manager (e.g., to a fluid source 505 from a fluid inlet of a cooling system (not shown)), and a cold side return pipe 707 configured to accept an exhaust of the second working fluid from the second fluid supply manager (e.g., from a fluid exhaust 519 to a fluid outlet of a cooling system (not shown)). It should be appreciated that any arrangement of the pipes 701, 703, 705, 707 may be used with various embodiments of the invention. For example, hot side pipes 701, 703 and cold side pipes 705, 707 may be arranged on opposite sides or on the same side of the thermoelectric device 700; return pipes 703, 707 and supply pipes 701, 705 may be arranged on the same or opposite sides of the thermoelectric device; the pipes 701, 703, 705, 707 may be combined into a fewer number of pipes such as one or more pipes that is divided and both supplies and returns the fluid through separate division. Furthermore, it should be appreciated that some embodiments of the invention may include a direct connection to working fluid sources or other fluid directing elements instead of or in addition to the pipes 701, 703, 705, 707.

As discussed above, each fluid supply manager 500 may be configured to direct the respective working fluid to and from a plurality of fluid flow managers that are configured to manage the flow of the working fluids proximate to respective sides of a plurality of thermoelectric modules, as described above.

One or more thermoelectric modules 200 may be disposed between the two fluid supply managers 500, as illustrated in FIG. 7. Each thermoelectric module 200 may be positioned such that each side of the thermoelectric module 200 is proximate to a respective fluid flow manager 217. As illustrated in FIG. 7, the one or more thermoelectric modules may be arranged in an array of thermoelectric modules.

In operation, the first and second working fluids may be supplied to the respective first and second fluid supply managers 500 from the hot and cold side supply pipes 701, 705. The working fluids may then be directed through the respective fluid supply manager 500 to the fluid flow managers 217 disposed on the fluid supply managers 500. Each working fluid may be passed proximally along a respective side of the thermoelectric modules 200 and exhausted from the fluid flow managers 217 back to the respective fluid supply manager 500. The fluid supply managers may then exhaust the working fluids through the hot and cold side fluid return pipes 703, 707.

As discussed above, when current exists through the thermoelectric module 200, one side of the thermoelectric module 200 heats up and the other side cools down. If a potential is applied across each thermoelectric module 200 through the electrical contact 409 of the fluid flow managers 217, as discussed above, a current exist through the thermoelectric module 200 and heat may travel from one side (i.e., the cold side) of the thermoelectric module 200 to the other side (i.e., the hot side). Also, heat will pass between the two sides and the working fluids traveling near the sides, such that the working fluid traveling proximate to the hot side becomes warm while the working fluid traveling proximate to the cold side becomes cold. If each of the thermoelectric modules 200 in a thermoelectric device 700 is arranged so that all the hot sides heat the same working fluid and all the cold sides cool the same working fluid, the array of thermoelectric modules 709 may produce a combined heating and cooling effect on the two working fluids.

The working fluids, one cooled by the thermoelectric modules 200, and the other warmed by the thermoelectric modules 200, may be directed through the hot and cold side return pipes 703, 707 to a target object or space to be used for heating and/or cooling. The working fluids may be heated and/or cooled a desired amount by increasing or decreasing the number of thermoelectric modules and/or thermoelectric devices used to heat and/or cool the working fluids. In some embodiments of the present invention, the thermoelectric modules 200 and/or thermoelectric devices 700 may be used to reduce the temperature of the working fluid that travel proximate to the cold side of each module to below zero degrees Celsius.

In some embodiments, while operating, the temperature difference between the warm side of the thermoelectric modules and the cold side of the thermoelectric modules may be about twenty degrees Celsius. In one embodiment, a temperature difference between the warm side of the thermoelectric modules 200 and the warmed working fluid after passing the thermoelectric modules 200 may be about three degrees Celsius. In one embodiment, a temperature difference between the cool side of the thermoelectric modules 200 and the cooled working fluid after passing the thermoelectric modules 200 may be about eight degrees Celsius.

To generate the current through the thermoelectric modules 200, each thermoelectric module 200 may be connected to one or more power supply through the electrical contacts 409 of the fluid flow managers 217, as discussed above. In some embodiments, the thermoelectric modules 200 may each be connected to a separate power supply. In other embodiments, some or all of the thermoelectric modules of a thermoelectric device may be connected to the same power supply. In some embodiments, the thermoelectric modules 200 may be electrically connected in series to the power supply. In other embodiments, the thermoelectric modules 200 may be electrically connected in parallel to the power supply.

In still other embodiments, the thermoelectric modules 200 may be electrically connected to the power supply with a combination of parallel and series connections. For example, in one implementation, the thermoelectric modules may be arranged into sets 711 that are each connected to one another in series, as shown in FIG. 7. The number of thermoelectric modules 200 in each set 711 may be determined based on the voltage output of the power supply. For example, if each thermoelectric module 200 requires sixteen volts, and a power supply produces a forty-eight volt output, each set 711 may be arranged to contain three thermoelectric modules 200 connected in series so that the total voltage requirement of the sets 711 equals forty-eight volts. In such an implementation, the sets 711 may be connected to the power supply in parallel. The number of sets 711 may be chosen based on a maximum or recommended power output of the power supply, for example, the number of sets 711 may be chosen so that the power needed to operate the sets 711 is about equal to the maximum or recommended power output of the power supply.

A thermoelectric device 700 in accordance with an embodiment of the present invention may be used to heat or cool any space or object. In some implementations, multiple chillers 700 may be used to increase heating or cooling of the working fluids. In some implementations, the thermoelectric device 700 may be used to cool an ice storage system, such as the one described in U.S. patent application Ser. No. ______, to Bean, filed concurrent, with the instant application, entitled “MODULAR ICE STORAGE FOR UNINTERRUPTIBLE CHILLED WATER,” and having attorney docket number A2000-705819, which is hereby incorporated herein by reference. In other implementations, a thermoelectric device may be used as part of another small process chiller.

Having thus described several aspects of at least one embodiment of this invention, it is to be appreciated various alterations, modifications, and improvements will readily occur to those skilled in the art. Such alterations, modifications, and improvements are intended to be part of this disclosure, and are intended to be within the spirit and scope of the invention. Accordingly, the foregoing description and drawings are by way of example only.

What is claimed is:

1. A thermoelectric system comprising:
at least one thermoelectric module comprising a first side and a second side, and being configured to develop a temperate difference between the first side and the second side during operation; and
at least one first fluid manager configured to direct a first fluid along at least a first portion of the first side of the at least one thermoelectric module.

2. The system of claim 1, wherein the first fluid includes at least one of water and a composition including glycol.

3. The system of claim 1, wherein the at least one thermoelectric module comprises at least one p-type semiconductor and at least one n-type semiconductor.

4. The system of claim 1, wherein the at least one thermoelectric module comprises at least one first fluid resistant layer configured to electrically insulate the first fluid from the first side.

5. The system of claim 1, wherein the at least one first fluid manager comprises at least one first fluid supply and at least one first fluid return.

6. The system of claim 5, further comprising a first fluid supply manager connection configured to direct the first fluid to the at least one first fluid supply and a first fluid return connection configured to direct the first fluid from the at least one first fluid return.

7. The system of claim 5, wherein the at least one first fluid supply comprises a plurality of first fluid supplies.

8. The system of claim 5, wherein the at least one first fluid manager further comprises at least one first fluid director forming at least one channel configured to direct at least a portion of the first fluid from the at least one first fluid supply to the at least one first fluid return.

9. The system of claim 1, wherein the at least one first fluid manager comprises at least one first turbulence element configured to generate turbulence in the first fluid along the at least first portion of the first side of the at least one thermoelectric module.

10. The system of claim 9, wherein the at least one first turbulence element comprises at least one first protrusion in a channel of the first fluid manager.

11. The system of claim 1, further comprising at least one second fluid manager configured to direct a second fluid along at least a second portion of the second side of the at least one thermoelectric module.

12. The system of claim 11, wherein the at least one thermoelectric module includes a plurality of thermoelectric modules, each having a respective first side and second side, wherein the at least one first fluid manager includes a plurality of first fluid managers each configured to direct at least a first portion of the first fluid proximally along at least a first portion of the respective first side of each thermoelectric module of the plurality of thermoelectric modules, and wherein the at least one second fluid manager includes a plurality of second fluid managers each configured to direct at least a second portion of the second fluid proximally along at least a second portion of the respective second side of each thermoelectric module of the plurality of thermoelectric modules.

13. The system of claim 1, wherein the at least one thermoelectric module is configured such that the first side and the second side experience a temperature difference of about twenty degrees Celsius when the at least one thermoelectric module is in operation.

14. The system of claim 1, wherein the first side comprises a hot side of the at least one thermoelectric module and the second side comprises a cold side of the at least one thermoelectric module.

15. The system of claim 14, wherein the at least one thermoelectric module is configured such that the hot side and first fluid experience a first temperature difference of about four degrees Celsius during operation of the at least one thermoelectric module and the cold side and second fluid experience a second temperature difference of about nine degrees Celsius during operation of the at least one thermoelectric module.

16. The system of claim 1, wherein the at least one thermoelectric module includes a plurality of thermoelectric modules, each having a respective first and second side, and wherein the at least one first fluid manager includes a plurality of first fluid managers each configured to direct at least a first portion of the first fluid proximally along a respective first portion of a respective first side of each thermoelectric module of the plurality of thermoelectric modules.

17. The system of claim 16, further comprising at least one power source electrically coupled to the plurality of thermoelectric modules.

18. The system of claim 17, wherein the plurality of thermoelectric modules are electrically coupled to one another.

19. The system of claim 18, wherein each thermoelectric module of a first subset of the plurality of thermoelectric modules is electrically coupled in series to other thermoelectric modules of the first subset.

20. The system of claim 19, wherein the first subset is electrically coupled in parallel to a plurality of second subsets of the plurality of thermoelectric modules.

21. The system of claim 20, wherein the first subset includes a number of thermoelectric modules corresponding to a voltage output of the power supply.

22. The system of claim 21, wherein the plurality of second subsets includes a number of subsets corresponding to a power output of the power supply.

23. A method of cooling comprising acts of:
A) generating a potential difference across at least one thermoelectric module to cool a first side of the at least one thermoelectric module and warm a second side of the at least one thermoelectric module; and
B) directing a first fluid along at least a first portion of at least one of the first side and the second side.

24. The method of claim 23, wherein the first fluid includes at least one of water and a composition including glycol.

25. The method of claim 23, wherein the act B includes directing the first fluid into at least one first fluid supply of at least one fluid manager and directing the first fluid out of at least one first fluid return of the at least one fluid manager.

26. The method of claim 25, wherein the act B further includes directing the first fluid through at least one fluid directing channel disposed in at least one fluid manager between the at least one fluid supply and the at least one fluid return.

27. The method of claim 26, wherein the act B further includes generating turbulence in the first fluid as the first fluid is directed through the at least one fluid directing channel.

28. The method of claim 23, wherein the act B comprises directing the first fluid along at least the first portion of the first side and directing a second fluid along at least a second portion of the second side.

29. The method of claim 23, wherein the act A includes generating a temperature difference between the first side and second side of about twenty degrees Celsius.

30. The method of claim 23, wherein the act A includes generating a first temperature difference between the first side and first fluid experience of about nine degrees Celsius and generating a second temperature difference between the second side and second fluid of about four degrees Celsius.

31. The method of claim 23, wherein the at least one thermoelectric module includes a plurality of thermoelectric modules.

32. The method of claim 31, further comprising an act of C) electrically coupling the plurality of thermoelectric modules to one another.

33. The method of claim 32, wherein the act C comprises electrically coupling each thermoelectric module of a first subset of the plurality of thermoelectric modules in series to other thermoelectric modules of the first subset.

34. The method of claim 33, the act C further comprises electrically coupling the first in parallel to a plurality of second subsets of the plurality of thermoelectric modules.

35. The method of claim 34, wherein the first subset includes a number of thermoelectric modules corresponding to a voltage output of a power supply coupled to the plurality of thermoelectric modules.

36. The method of claim 35, wherein the plurality of second subsets includes a number of subsets corresponding to a power output of the power supply.

37. A cooling system comprising:
at least one first fluid inlet;
at least one first fluid outlet; and
at least one direct thermoelectric device disposed between the at least one first fluid inlet and the at least one first fluid outlet, the at least one direct thermoelectric device being configured to cool at least one first fluid supplied from the at least one first fluid inlet and supply the at least one cooled first fluid to the at least one first fluid outlet.

38. The system of claim 37, wherein the at least one first fluid includes at least one of water and a composition including glycol.

39. The system of claim 37, wherein the at least one direct thermoelectric device comprises:
at least one thermoelectric module comprising a first side; and
at least one first fluid manager configured to accept the at least one first fluid from the at least one first fluid inlet, direct the at least one first fluid along at least a first portion of the first side of the at least one thermoelectric module, and exhaust the at least one cooled first fluid to the at least one first fluid outlet.

40. The system of claim 39, wherein the at least one thermoelectric module comprises at least one first fluid resistant layer configured to electrically separate the first fluid from the first side

41. The system of claim 39, wherein the at least one first fluid manager comprises at least one first turbulence element configured to generate turbulence proximally along the at least first portion of the first side of the at least one thermoelectric module.

42. The system of claim 37, further comprising:
at least one second fluid inlet;
at least one second fluid outlet; and
wherein the at least one direct thermoelectric device is disposed between the at least one second fluid inlet and the at least one second fluid outlet, the at least one direct thermoelectric device being further configured to warm at least one second fluid supplied from the at least one second fluid inlet and supply the at least one warmed second fluid to the at least one second fluid outlet.

43. The system of claim 42, wherein the at least one direct thermoelectric device comprises:
at least one thermoelectric module comprising a first side and a second side;
at least one first fluid manager configured to accept the at least one first fluid from the at least one first fluid inlet, direct the at least one first fluid along at least a first portion of the first side of the at least one thermoelectric module, and exhaust the at least one cooled first fluid to the at least one first fluid outlet; and
at least one second fluid manager configured to accept the at least one second fluid from the at least one second fluid inlet, direct the at least one second fluid along at least a second portion of the second side of the at least one thermoelectric module, and exhaust the at least one warmed second fluid to the at least one second fluid outlet.

44. The system of claim 43, wherein the at least one thermoelectric module is configured such that the first side and second side experience a temperature difference of about twenty degrees Celsius when the at least one thermoelectric module is in operation.

45. The system of claim 43, wherein the at least one thermoelectric module is configured such that the first side and the cooled first fluid experience a first temperature difference of about nine degrees Celsius during operation of the at least one thermoelectric module and the second side and warmed second fluid experience a second temperature difference of about four degrees Celsius during operation of the at least one thermoelectric module.
